(19) United States
(12) Patent Application Publication
(10) Pub. No.: US 2013/0240997 A1
(43) Pub. Date: Sep. 19, 2013

(54) CONTACT BARS FOR MODIFYING STRESS IN SEMICONDUCTOR DEVICE AND RELATED METHOD

(71) Applicants: Brent A. Anderson, Jericho, VT (US); Andres Bryant, Burlington, VT (US); William F. Clark, JR., Essex Junction, VT (US); Edward J. Nowak, Essex Junction, VT (US)

(72) Inventors: Brent A. Anderson, Jericho, VT (US); Andres Bryant, Burlington, VT (US); William F. Clark, JR., Essex Junction, VT (US); Edward J. Nowak, Essex Junction, VT (US)

(73) Assignee: INTERNATIONAL BUSINESS MACHINES CORPORATION, Armonk, NY (US)

(21) Appl. No.: 13/424,319

(22) Filed: Mar. 19, 2012

(51) Int. Cl. H01L 27/11; H01L 21/8238; H01L 27/092

(52) U.S. Cl. 257/369; 438/233; 257/E27.062; 257/E27.098; 257/E21.641

(57) ABSTRACT

Solutions for forming stress optimizing contact bars and contacts are disclosed. In one aspect, a semiconductor device is disclosed including an n-type field effect transistor (NFET) having source/drain regions; a p-type field effect transistor (PFET) having source/drain regions; a stress inducing layer over both the NFET and the PFET, the stress inducing layer inducing only one of a compressive stress and a tensile stress; a contact bar extending through the stress inducing layer and coupled to at least one of the source/drain regions of a selected device of the PFET and the NFET to modify a stress induced in the selected device compared to a stress induced in the other device; and a round contact extending through the stress inducing layer and coupled to at least one of the source/drain regions of the other device of the PFET and the NFET.

### BACKGROUND OF THE INVENTION

The subject matter disclosed herein relates to contact bars for modifying stress in a semiconductor device, and a related method.

Stress inducing layers (e.g., nitride liners) have been used to increase stress in semiconductor devices for the purpose of improving device performance. When applied in a longitudinal direction (i.e., in the direction of current flow), tensile stress is known to enhance electron mobility (or NFET drive currents) while compressive stress is known to enhance hole mobility (or PFET drive currents). While these stress layers may positively impact performance of one portion of a device (e.g., an NFET), the same stress inducing layer may negatively impact performance of a second portion of a device (e.g., a PFET). Applying dual-stress liners (DSL) is one approach that has been used to solve this problem. However, the DSL approach has its own disadvantages in that they require multiple deposition and masking steps. One illustrative process may include applying a compressive stress type liner over both the PFET and the NFET, and then removing it over the inappropriate device, i.e., the NFET, and then applying a tensile stress liner over both devices, contacting the NFET, and then removing it over the PFET. These steps are time-consuming, costly, and may introduce process variations when fabricating a plurality of semiconductor devices.

### BRIEF DESCRIPTION OF THE INVENTION

A first aspect of the disclosure provides a semiconductor device comprising: an n-type field effect transistor (NFET) having source/drain regions; a p-type field effect transistor (PFET) having source/drain regions; a stress inducing layer over both the NFET and the PFET, the stress inducing layer inducing only one of a compressive stress and a tensile stress; a contact bar extending through the stress inducing layer and coupled to at least one of the source/drain regions of a selected device of the PFET and the NFET to modify a stress induced in the selected device compared to a stress induced in the other device; and a round contact extending through the stress inducing layer and coupled to at least one of the source/drain regions of the other device of the PFET and the NFET.

A second aspect of the disclosure provides a method comprising: forming an n-type field effect transistor (NFET) having source/drain regions; forming a p-type field effect transistor (PFET) having source/drain regions; forming a stress inducing layer over both the NFET and the PFET, the stress inducing layer inducing only one of a compressive stress and a tensile stress; and modifying a stress induced in a selected device of the PFET and the NFET compared to a stress induced in the other device by: forming a contact bar extending through the stress inducing layer and coupled to at least one of the source/drain regions of the selected device, and forming a round contact extending through the stress inducing layer and coupled to at least one of the source/drain regions of the other device.

A third aspect of the disclosure provides a semiconductor device comprising: an n-type field effect transistor (NFET) having source/drain regions; a p-type field effect transistor (PFET) having source/drain regions; a stress inducing layer over both the NFET and the PFET, the stress inducing layer inducing only one of a compressive stress and a tensile stress; and wherein in the case that the stress inducing layer includes the compressive stress, the semiconductor device further includes a contact bar extending through the stress inducing layer and coupled to at least one of the source/drain regions of the NFET, and a round contact to each of the source/drain regions of the PFET, and wherein in the case that the stress inducing layer includes the tensile stress, the semiconductor device further includes a contact bar extending through the stress inducing layer and coupled to at least one of the source/drain regions of the PFET, and a round contact to each of the source/drain regions of the NFET.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a schematic top view of a portion of a semiconductor device according to embodiments of the invention.

FIG. 2 shows a schematic top view of a portion of a semiconductor device according to another embodiment of the invention.

FIG. 3 shows a schematic top view of a portion of an SRAM structure according to embodiments of the invention.

FIG. 4 shows a schematic top view of a portion of an asymmetric device according to embodiments of the invention.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

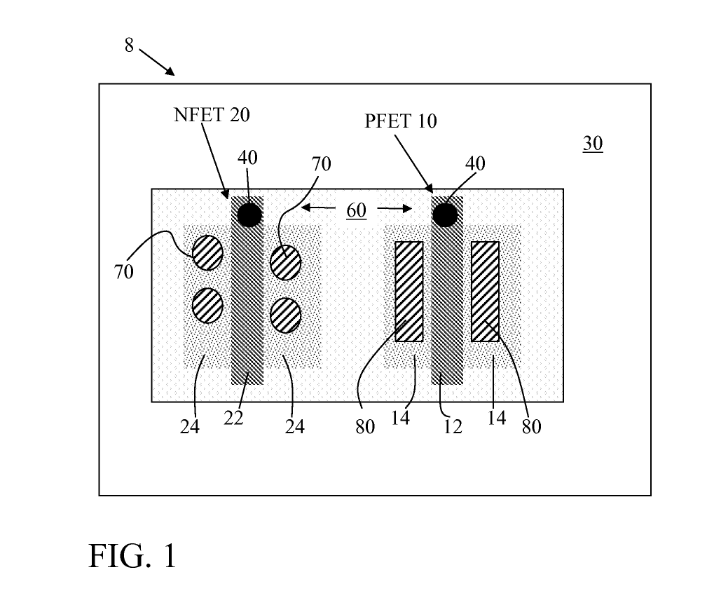

The subject matter disclosed herein relates to contact bars and round contacts for modifying stress in a semiconductor device. Turning to the drawings, FIG. 1 shows a schematic top view of a portion of a semiconductor device (or, structure) 8 according to embodiments of the invention. Semiconductor device 8 may include a p-type field effect transistor (PFET) 10 and an n-type field effect transistor (NFET) 20. As is known in the art, PFET 10 and NFET 20 may include and/or be formed over portions of a substrate 30, where substrate 30 is shown in this top view as at least partially covered by components of PFET 10, NFET 20. Substrate 30 may include one or more materials such as silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or the entire semiconductor substrate 30 may be stressed. For example, the substrate included in semiconductor device 8 may be stressed. In one embodiment, the substrate is silicon based.

PFET 10 and NFET 20 may include any now known or later developed transistor structures. For example, PFET 10 may include at least one PFET gate 12 having adjacent source/drain regions 14. Similarly, NFET 20 may include at least one NFET gate 22 and adjacent source/drain regions 24. Gates 12, 22 may be contacted by other devices located over semiconductor device 8 via one or more gate contacts 40. Other conventional components, omitted herein for clarity, may include isolation regions, spacers, etc. As shown and described herein, it is understood that each of PFET 10 and NFET 20 may include, respectively, any known logic PFET and logic NFET components. PFET 10 and NFET 20 may be formed using any now known or later developed semiconductor fabrication techniques.

Semiconductor device 8 also includes a stress inducing layer 60 applied over both PFET 10 and NFET 20 to induce a one of a compressive stress and a tensile stress, i.e., a particular stress, in both devices. Stress inducing layer 60 may be used to improve performance-related aspects of at least one FET (e.g., PFET or NFET), and may include a conventional nitride-based stress inducing layer. Stress inducing layer 60 may be formed (e.g., deposited, epitaxially grown, etc.) over PFET 10 and NFET 20 in one or more steps. In one embodiment, stress inducing layer 60 may include a compressive stress inducing layer (e.g., a compressive stress nitride) applying a compressive stress in a direction parallel to the gate channel of each of PFET 10 and NFET 20. As is known in the art, compressive stress inducing layer 60 may improve the performance of PFET 10 (e.g., through increased drive current through a channel of gate 12). However, this same compressive stress inducing layer 60 applied in a direction parallel to the gate channel (under gate 22) of NFET 20 may degrade the performance (e.g., through decreased drive current) of that NFET 20. Alternatively, stress inducing layer 60 may includes a tensile stress inducing layer (e.g., a tensile stress nitride) applying a tensile stress in a direction parallel to the gate channel of each of PFET 10 and NFET 20. As is known in the art, tensile stress inducing layer 60 may improve the performance of NFET 20 (e.g., through increased drive current through a channel of gate 22). However, this same tensile stress inducing layer 60 applied in a direction parallel to the gate channel (under gates 12) of PFET 10 may degrade the performance of PFET 10. As indicated herein, conventional approaches include applying dual-stress liners to enhance the performance of both an NFET and a PFET. These approaches may require additional masking and deposition steps in order to form distinct stress layers over the logic PFET and logic NFET. In contrast to these conventional approaches, aspects of the invention provide for forming a single-type (e.g., compressive or tensile) stress inducing layer 60 over both PFET 10 and NFET 20, and decreasing the negative effect that stress inducing layer 60 has on one of PFET 10 or NFET 20 by forming stress-modifying contact bars to the source/drain regions of the adversely impacted PFET 10 or NFET 20.

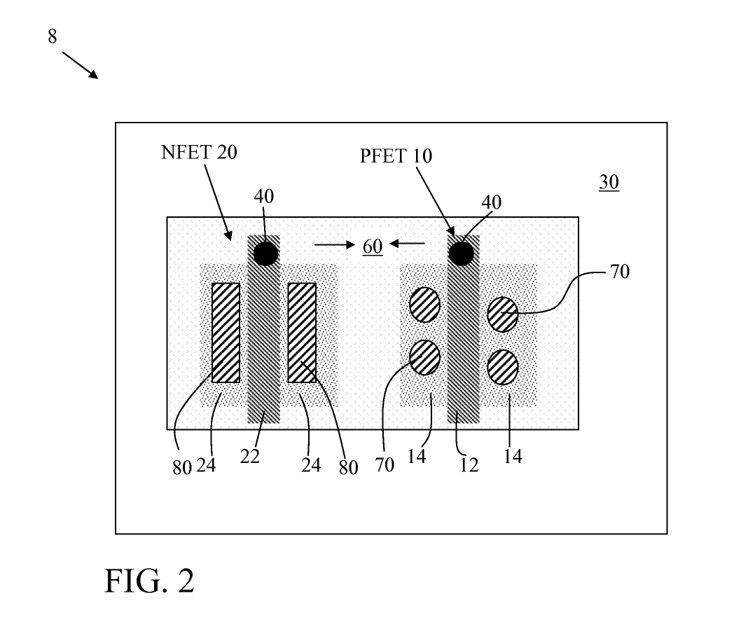

In one embodiment, shown in FIGS. 1 and 2, as indicated above, semiconductor logic device 8 includes logic PFET 10 and logic NFET 20 and stress inducing layer 60 over both FETs. Further, semiconductor device 8 includes a contact bar 80 extending through stress inducing layer 60 and coupled to at least one of source/drain regions 14 of a selected device of PFET 10 and NFET 20 to modify a stress induced in the selected device compared to a stress induced in the other device.

In FIG. 1, stress inducing layer 60 includes a tensile stress and contact bars 80 are within at least one (shown as both) source/drain regions 14 of PFET 10 to reduce the tensile stress applied to PFET 10. That is, in the case that stress inducing layer 60 includes a tensile stress, the selected device includes PFET 10 and contact bar 80 extends through the stress inducing layer and is coupled to at least one of the source/drain regions 14 of PFET 10. In this example, stress inducing layer 60 includes a tensile stress inducing layer configured to improve the performance of the NFET 20. Tensile stress inducing layer 60 in this case can contribute to diminished performance of PFET 10. As such, contact bars 80 can be formed to reduce the stress on PFET 10, thereby mitigating the negative effects of the tensile stress inducing layer 60 on the PFET's performance.

In contrast, in FIG. 2, stress inducing layer 60 includes a compressive stress and contact bars 80 are within at least one (shown as both) source/drain regions 24 of NFET 20 to reduce the compressive stress applied to NFET 20. That is, in the case that stress inducing layer 60 includes the compressive stress, the selected device includes NFET 20 and contact bar 80 extends through stress inducing layer 60 and is coupled to at least one of source/drain regions 24 of NFET 20. In this example, stress inducing layer 60 includes a compressive stress inducing layer configured to improve the performance of the PFET 10. Compressive stress inducing layer 60 can contribute to diminished performance of NFET 20. As such, contact bars 80 can be formed to reduce the stress on NFET 20, thereby mitigating the negative effects of the compressive stress inducing layer 60 on the NFET's performance.

In either situation illustrated in FIGS. 1-2, a round contact 70 extends through stress inducing layer 60 and is coupled to at least one of the source/drain regions of the other device of PFET 10 and NFET 20, i.e., the one without the contact bar. In FIG. 1, round contact 70 is positioned within at least one (shown as both) source/drain regions 24 of NFET 20 to maintain the tensile stress applied to NFET 20. In contrast, in FIG. 2, round contact 70 is positioned within at least one (shown as both) source/drain regions 14 of PFET 10 to maintain the compressive stress applied to PFET 20. In one embodiment, round contact(s) 70 have an aspect ratio of approximately 1:1 to approximately 1.5:1, and contact bar(s) 80 have an aspect ratio of approximately 3:1 to approximately 20:1. The aspect ratio is the ratio lateral length (longest length parallel to gate) to width (perpendicular to gate). Although two round contacts 70 and one contact bar 80 are shown to each respective source/drain region in each embodiment, it is understood that more or less round contacts 70 may be employed and more contact bars 80 may be employed. Round contacts 70 and/or contact bars 80 may be employed as dummy contacts, i.e., they carry no signals, or as active, signal-carrying contacts.

Round contact(s) 70 may be formed, for example, as any conventional substantially round contact via, e.g., masking, etching, exposure and/or deposition. In one embodiment, round contact 70 is formed by: masking and etching/exposing to form openings in the stress inducing layer 60 (after it is formed over PFET 10 and NFET 20) to the source/drain regions 14, 24; and depositing a conventional contact metal (e.g., copper, tungsten, nickel, etc.) to form round contact 70 extending to the source/drain regions 14, 24. An appropriate refractory metal liner may or may not be used. Round contacts 70 are referred to as ‘round’ to distinguish them from contact bars 80, which have a more significant lateral length. However, as known in the art, round contacts 70 may not be absolutely round or circular in cross-section. Contact bar(s) 80 may be similarly formed as round contacts 70, however, contact bars 80 can be configured to form rectangular or otherwise elongated shapes extending along the direction of a nearby gate (e.g., gate 12 or 22). Contact bars 80 may be formed, for example, via masking, etching, exposure and/or deposition. In one embodiment, contact bar 80 is formed by: masking and etching/exposing to form an opening in stress inducing layer 60 (after it is formed over PFET 10 and NFET 20) to the source/drain regions 14, 24; and depositing a conventional contact metal (e.g., copper, tungsten, nickel, etc.) to form contact bar 80 extending to the source/drain regions 14, 24. In another embodiment, a conventional contact metal may be plated, grown, etc., in the openings within stress inducing layer 60 to form contact bars 80. An appropriate refractory metal liner may or may not be used in either case. Contact bars 80 can resemble a rectangular bar (from the top-down views herein), and can extend a substantial portion (over half) of the length of a gate (e.g., gate 12 or 22). As noted herein, contact bar(s) 80 can have an aspect ratio of approximately 3:1 to approximately 20:1, in contrast to traditional round contacts 70.

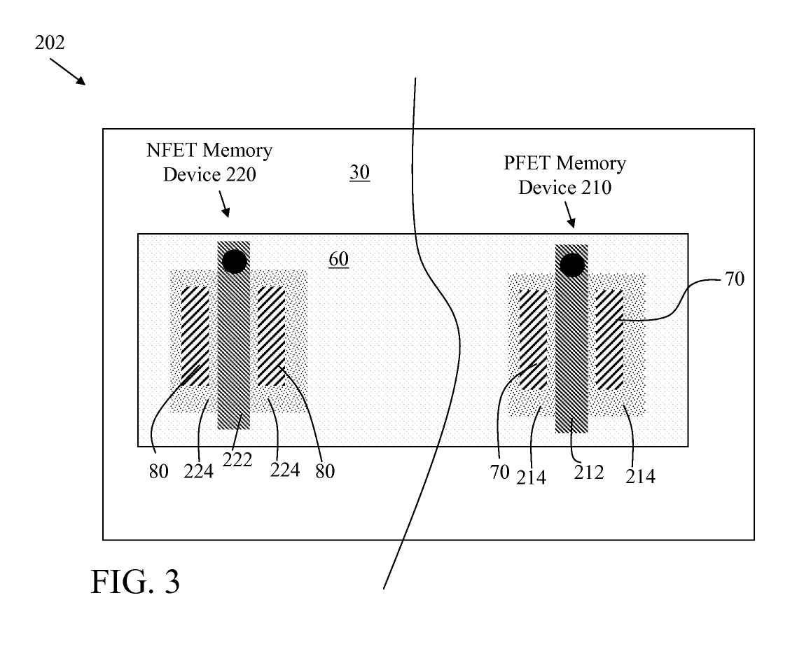

It is understood that the teachings of this disclosure may be applied to a plurality of semiconductor devices in order to simplify fabrication, reduce process variations across a plurality of devices, and/or reduce costs. As shown in FIG. 3, in addition to the embodiments shown in FIGS. 1 and 2, the use of one or more contact bars 80 may be employed to improve performance in both an NFET and PFET included within a static random access memory (SRAM) structure 202, i.e., at another location within semiconductor device 8. In this case, as shown in FIG. 3, an SRAM structure 202 is shown including a p-type field effect transistor (PFET) memory (analog) device 210 having source/drain regions 214, and an n-type field effect transistor (NFET) memory (analog) device 220 having source/drain regions 224. Stress inducing layer 60 extends over both the NFET memory device and the PFET memory device.

A contact bar 80 extends through stress inducing layer 60 and is coupled to each of the source/drain regions 214 or 224 of a selected memory device of PFET memory device 810 and NFET memory device 820 to decrease resistance in the selected memory device compared to a resistance in the other memory device. That is, a contact bar 80 extends through stress inducing layer 60 over the source/drain regions (214 or 224) of either PFET memory device 810 or NFET memory device 820 depending on whether the stress is compressive or tensile. Although shown together for brevity, it is understood that PFET memory device 810 and NFET memory device 820 may not be used together. Similar to those shown in FIGS. 1-2, a round contact 70 may extend through stress inducing layer 60 to each of the source/drain regions of the other memory device. Alternatively, a contact bar 80 may extend through stress inducing layer 60 to source/drain regions 214, 224 of each of NFET memory device 220 and PFET memory device 210 to decrease current variability in SRAM structure 202. In this case, both structures as illustrated in FIG. 3 are employed together.

Contact bars 80 in an SRAM structure 202 can be used to provide performance benefits in the memory device. As is known in the art, an SRAM structure 202 is a form of memory device which uses bistable latching circuitry to store each bit of memory. In this embodiment, as in those shown and described with reference to FIGS. 1-2, contact bars 80 may improve performance of the underlying PFET memory device 210 and NFET memory device 220 by modifying the stress caused by stress inducing layer 60 (tensile and/or compressive). In addition, when used in an SRAM structure 202, contact bars 80 may increase the capacitance of SRAM structure 202, making the device more stable (e.g., less likely to flip between storage states). In this embodiment, stress inducing layer 60 may be formed of a substantially consistent stress-inducing material (across both PFET memory device 210 and NFET memory device 220), or may be formed of different materials (e.g., as a dual-stress liner including a compressive and a tensile stress layer). In any case, contact bars 80 may help to increase the capacitance of SRAM structure 202, thereby making the SRAM structure more stable. Contact bars 80 also will cause decreased resistance due to their large contact cross-sectional areas (e.g., extending substantially the entire width of PFET source/drain region 214 or NFET source/drain region 224, respectively). Further, SRAM structures 202 including stress inducing layers 60 typically exhibit variations in process parameters compared with SRAM structures not including stress inducing layers. Contact bars 80 act to decrease the effect of the stress inducing layers 60 on current variability across a plurality of SRAM structures.

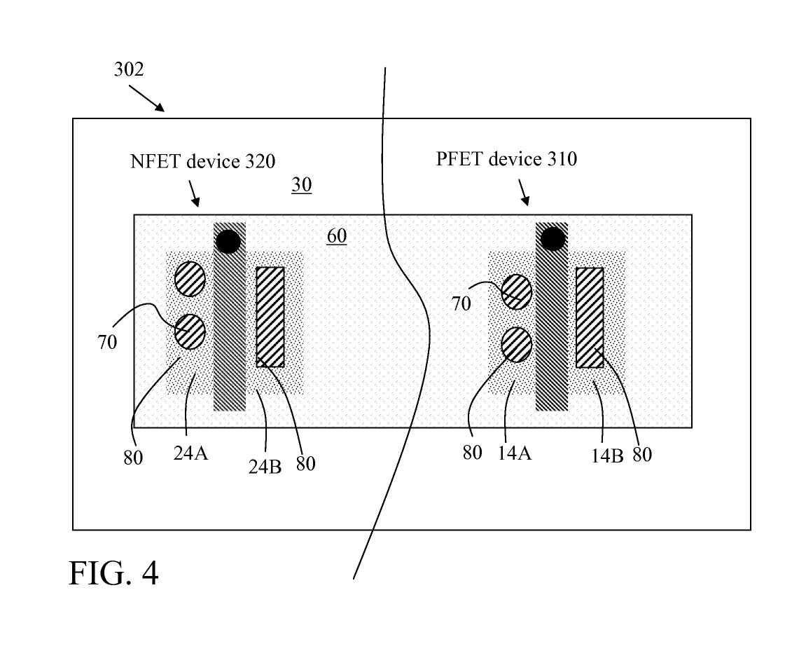

FIG. 4 illustrates an example of an asymmetric device 302 that can be used in another part of semiconductor device 8 (FIGS. 1-2) along with the devices of FIGS. 1-3. As used herein, “asymmetric” indicates that stress and resistance is asymmetric across the device, i.e., on opposite sides of the gate. In this case, asymmetric device 302 includes a field effect transistor (FET) device such as a PFET device 310 or an NFET device 320 having source/drain regions 14A, 14B, or 24A, 24B, respectively. Stress inducing layer 60 extends over the FET device 310 or 320. A contact bar 80 extends through stress inducing layer 60 to a selected one of source/drain regions 14B (or 24B) of the FET device 310 (or 320) to reduce resistance on the selected one of the source/drain regions compared to the other one of the source/drain regions 14A (24A). A round contact 70 extend through stress inducing layer 60 to the other one of the source/drain regions 14A (or 24A) of the FET device to provide a higher stress on the other one of the source/drain regions 14A (or 24A) of the FET device compared to the selected one of the source/drain regions of the FET device. In other words, the source/drain region with contact bar 80 thereto will exhibit reduced resistance and less stress versus the source/drain region with round contact 70. NFET device 320 and PFET device 310 may be used together or separately.

In another embodiment, a method may include forming NFET 20 having source/drain regions 24, and forming PFET 10 having source/drain regions 14 using any now known or later developed techniques. A stress inducing layer 60 may then be formed over both NFET 20 and PFET 10, the stress inducing layer inducing only one of a compressive stress and a tensile stress. Stress inducing layer 60 may be formed by any now known or later developed deposition technique or DSL technique. As described herein, a stress induced in a selected device of PFET 10 and NFET 20 may be modified compared to a stress induced in the other device by: forming a contact bar 80 extending through the stress inducing layer and coupled to at least one of the source/drain regions of the selected device, and forming a round contact 70 extending through the stress inducing layer and coupled to at least one of the source/drain regions of the other device.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

What is claimed is:

1. A semiconductor device comprising:
an n-type field effect transistor (NFET) having source/drain regions;
a p-type field effect transistor (PFET) having source/drain regions;
a stress inducing layer over both the NFET and the PFET, the stress inducing layer inducing only one of a compressive stress and a tensile stress;
a contact bar extending through the stress inducing layer and coupled to at least one of the source/drain regions of a selected device of the PFET and the NFET to modify a stress induced in the selected device compared to a stress induced in the other device; and
a round contact extending through the stress inducing layer and coupled to at least one of the source/drain regions of the other device of the PFET and the NFET.

2. The semiconductor device of claim 1, wherein in the case that the stress inducing layer includes the compressive stress, the selected device includes the NFET and the contact bar extends through the stress inducing layer and is coupled to at least one of the source/drain regions of the NFET, and wherein the round contact includes a round contact to each of the source/drain regions of the PFET.

3. The semiconductor device of claim 1, wherein in the case that the stress inducing layer includes the tensile stress, the selected device includes the PFET and the contact bar extends through the stress inducing layer and is coupled to at least one of the source/drain regions of the PFET, and wherein the round contact includes a round contact to each of the source/drain regions of the NFET.

4. The semiconductor device of claim 1, wherein the contact bar has an aspect ratio of approximately 3:1 to approximately 20:1, and the round contact has an aspect ration of approximately 1:1 to approximately 1.5:1.

5. The semiconductor device of claim 1, further comprising a static random access memory (SRAM) structure including:
an n-type field effect transistor (NFET) memory device having source/drain regions, a p-type field effect transistor (PFET) memory device having source/drain regions, and wherein the stress inducing layer extends over both the NFET memory device and the PFET memory device; and
a contact bar extending through the stress inducing layer and coupled to each of the source/drain regions of a selected memory device of the PFET memory device and the NFET memory device to decrease resistance in the selected memory device compared to a resistance in the other memory device.

6. The semiconductor device of claim 5, further comprising a round contact extending through the stress inducing layer to each of the source/drain regions of the other memory device.

7. The semiconductor device of claim 5, further comprising a contact bar extending through the stress inducing layer to the source/drain regions of each of the NFET memory device and the PFET memory device to decrease current variability in the SRAM structure.

8. The semiconductor device of claim 1, further comprising an asymmetric device including:
a field effect transistor (FET) device having source/drain regions, wherein the stress inducing layer extends over the FET device;
a first contact bar extending through the stress inducing layer to a selected one of the source/drain regions of the FET device to reduce resistance on the selected one of the source/drain regions compared to the other one of the source/drain regions, and
a first round contact extending through the stress inducing layer to the other one of the source/drain regions of the FET device to provide a higher stress on the other one of the source/drain regions of the FET device compared to the selected one of the source/drain regions of the FET device.

9. A method comprising:
forming an n-type field effect transistor (NFET) having source/drain regions;
forming a p-type field effect transistor (PFET) having source/drain regions;
forming a stress inducing layer over both the NFET and the PFET, the stress inducing layer inducing only one of a compressive stress and a tensile stress; and
modifying a stress induced in a selected device of the PFET and the NFET compared to a stress induced in the other device by:
forming a contact bar extending through the stress inducing layer and coupled to at least one of the source/drain regions of the selected device, and
forming a round contact extending through the stress inducing layer and coupled to at least one of the source/drain regions of the other device.

10. The method of claim 9, wherein in the case that the stress inducing layer includes the compressive stress, the selected device includes the NFET and the contact bar forming includes extending the contact bar through the stress inducing layer to couple to at least one of the source/drain regions of the NFET, and further comprising forming a round contact to each of the source/drain regions of the PFET.

11. The method of claim 9, wherein in the case that the stress inducing layer includes the tensile stress, the selected device includes the PFET and the contact bar forming includes extending the contact bar through the stress inducing layer to couple to at least one of the source/drain regions of the PFET, and further comprising forming a round contact to each of the source/drain regions of the NFET.

12. The method of claim 9, wherein the contact bar forming includes coupling the contact bar to only one of the at least one source/drain regions of the selected device.

13. The method of claim 9, wherein the contact bar has an aspect ratio of approximately 3:1 to approximately 20:1, and the round contact has an aspect ratio of approximately 1:1 to approximately 1.5:1.

14. A semiconductor device comprising:
an n-type field effect transistor (NFET) having source/drain regions;
a p-type field effect transistor (PFET) having source/drain regions;
a stress inducing layer over both the NFET and the PFET, the stress inducing layer inducing only one of a compressive stress and a tensile stress; and
wherein in the case that the stress inducing layer includes the compressive stress, the semiconductor device further includes a contact bar extending through the stress inducing layer and coupled to at least one of the source/drain regions of the NFET, and a round contact to each of the source/drain regions of the PFET, and
wherein in the case that the stress inducing layer includes the tensile stress, the semiconductor device further includes a contact bar extending through the stress inducing layer and coupled to at least one of the source/drain regions of the PFET, and a round contact to each of the source/drain regions of the NFET.

15. The semiconductor device of claim 14, wherein the round contact has an aspect ratio of approximately 1:1 to approximately 1.5:1, and the contact bar has an aspect ratio of approximately 3:1 to approximately 20:1.

16. The semiconductor device of claim 14, further comprising a static random access memory (SRAM) structure including:
an n-type field effect transistor (NFET) memory device having source/drain regions, a p-type field effect transistor (PFET) memory device having source/drain regions, and wherein the stress inducing layer extends over both the NFET memory device and the PFET memory device; and
a contact bar extending through the stress inducing layer and coupled to each of the source/drain regions of a selected memory device of the PFET memory device and the NFET memory device to decrease resistance in the selected memory device compared to a resistance in the other memory device.

17. The semiconductor device of claim 16, further comprising a round contact extending through the stress inducing layer to each of the source/drain regions of the other memory device.

18. The semiconductor device of claim 16, further comprising a contact bar extending through the stress inducing layer to the source/drain regions of each of the NFET memory device and the PFET memory device to decrease current variability in the SRAM structure.

19. The semiconductor device of claim 14, further comprising an asymmetric device including:
a field effect transistor (FET) device having source/drain regions, wherein the stress inducing layer extends over the FET device;
a first contact bar extending through the stress inducing layer to a selected one of the source/drain regions of the FET device to reduce resistance on the selected one of the source/drain regions compared to the other one of the source/drain regions, and a first round contact extending through the stress inducing layer to the other one of the source/drain regions of the FET device to provide a higher stress on the other one of the source/drain regions of the FET device compared to the selected one of the source/drain regions of the FET device.
